(19) United States
(12) Patent Application Publication
(10) Pub. No.: US 2026/0231817 A1
(43) Pub. Date: Aug. 6, 2026

(54) EPOXY RESIN COMPOSITION, ELECTRONIC COMPONENT, SEMICONDUCTOR DEVICE, AND SEMICONDUCTOR DEVICE MANUFACTURING METHOD

(71) Applicant: NAMICS CORPORATION, Niigata (JP)

(72) Inventors: Yu SAITO, Niigata (JP); Takayuki OE, Niigata (JP); Tsuyoshi KAMIMURA, Niigata (JP)

(21) Appl. No.: 19/153,988

(22) PCT Filed: Oct. 2, 2023
(86) PCT No.: PCT/JP2023/035949

§ 371 Date: Aug. 6, 2025

(30) Foreign Application Priority Data
Mar. 28, 2023 (JP) 2023-052250

(51) Int. Cl. H10W 76/47; C08K 3/36; C08K 5/17; C08K 5/3445; C08L 63/00; H10P 52/40; H10W 76/05

(52) U.S. Cl. CPC H10W 76/47; C08K 3/36; C08K 5/17; C08K 5/3445; C08L 63/00; H10P 52/409; H10W 76/05; C08L 2207/53

(57) ABSTRACT

To provide an epoxy resin composition capable of suppressing small pores generated when a surface of a cured product is polished, an electronic component using the epoxy resin composition, a semiconductor device using the epoxy resin composition, and a method for manufacturing the semiconductor device. The epoxy resin composition includes an epoxy resin, a curing accelerator, a filler, and an elastomer. The elastomer is at least one selected from a solid elastomer and a liquid elastomer, and the solid elastomer has a structure having no double bond in the main chain.

### TECHNICAL FIELD

The present invention relates to an epoxy resin composition, an electronic component, a semiconductor device, and a method for manufacturing a semiconductor device.

### BACKGROUND ART

Semiconductor devices on which semiconductor elements are mounted, such as personal computers and smartphones, have been rapidly reduced in size and increased in functionality. Accordingly, improvement of a method for mounting a semiconductor element has been advanced. An example thereof is improvement in a method for preparing a package.

Since a package was conventionally prepared after a semiconductor element was divided into segments, the size of the package was always larger than that of the semiconductor element. For this reason, a package obtained by the conventional method for preparing a package could not be mounted on a small semiconductor device.

Therefore, a technique of preparing a package in a state of a wafer before dividing a semiconductor element into segments (wafer level chip size package technology) is used.

In the wafer level chip size package technique, there is a step of sealing a semiconductor element with a sealing material. As a sealing method suitable for the wafer level chip size packaging technique, there is compression molding. The compression molding is a method in which a liquid sealing material called a liquid compression molding material is placed in a void below a semiconductor element, and the sealing material is cured.

As such a liquid sealing material, for example, a composition containing an epoxy resin, a curing agent, and a filler is proposed in Patent Literatures 1 and 2.

### CITATION LIST

### Patent Literature

Patent Literature 1: WO 2018/221681 A
Patent Literature 2: JP-A-2015-105304

### SUMMARY OF INVENTION

### Problems to be Solved by Invention

In the wafer level chip size package technique, sealing is performed with a sealing material, and a rewiring layer is thereafter formed in a portion corresponding to a circuit surface of a semiconductor element in a cured product of the sealing material. Here, before the rewiring layer is formed, the surface of the cured product of the sealing material is polished by a chemical mechanical polishing (CMP) method or the like to flatten the surface of the cured product.

However, when the surface of the cured product of the sealing material is polished using the CMP method, small pores may be generated on the surface of the cured product. Such small pores may affect the uniformity of the thickness of the rewiring layer. When the thickness of the rewiring layer is not uniform, contact between the rewiring layer and the circuit surface of the semiconductor element or a solder ball becomes poor. As a result, when the semiconductor element is mounted on a semiconductor device, electrical connection between the semiconductor element and other semiconductor elements or the like may not be uniform, and a failure may occur in the semiconductor device.

An object of the present invention is to provide an epoxy resin composition capable of suppressing small pores generated when a surface of a cured product is polished, an electronic component using the epoxy resin composition, a semiconductor device using the epoxy resin composition, and a method for manufacturing the semiconductor device.

### Solution to Problems

In order to achieve the above object, embodiments of the present invention are as follows.

(1) An epoxy resin composition including an epoxy resin, a curing accelerator, a filler, and an elastomer, in which
the elastomer is at least one selected from a solid elastomer and a liquid elastomer, and
the solid elastomer has a structure having no double bond in a main chain.

(2) The epoxy resin composition according to (1), in which after a surface of a cured product of the epoxy resin composition is polished by first polishing for rough polishing and second polishing for polishing with a liquid containing a polishing agent, the number of pores having a diameter of 0.05 μm to 0.5 μm present on the surface of the cured product is 10 or less per predetermined area.

(3) The epoxy resin composition according to (1) or (2), in which a content of the elastomer is 5.0 mass % or more with respect to components of the epoxy resin composition excluding the filler.

(4) The epoxy resin composition according to any one of (1) to (3), in which the solid elastomer is a core-shell type.

(5) The epoxy resin composition according to any one of (1) to (4), in which a content of the elastomer is 5.0 mass % to 20.0 mass % with respect to components of the epoxy resin composition excluding the filler.

(6) The epoxy resin composition according to any one of (1) to (5), in which a content of the filler is 73.0 mass % to 87.5 mass %.

(7) The epoxy resin composition according to any one of (1) to (6), having a viscosity at 120° C. of 0.5 Pa's to 40.0 Pa·s.

(8) The epoxy resin composition according to any one of (1) to (7), in which the curing accelerator is a heterocyclic compound containing a nitrogen atom.

(9) The epoxy resin composition according to any one of (1) to (8), including at least one curing agent selected from a phenolic curing agent, an amine-based curing agent, and an acid anhydride-based curing agent.

(10) The epoxy resin composition according to any one of (1) to (9), in which the epoxy resin is at least one selected from an aliphatic epoxy resin and an aromatic epoxy resin.

(11) The epoxy resin composition according to any one of (1) to (10), which is used as a liquid compression molding material.

(12) An electronic component including a support and the cured product of the epoxy resin composition according to any one of (1) to (11).

(13) A semiconductor device including the electronic component according to (12).

(14) A method for manufacturing a semiconductor device, including: a step of filling a void between a support and a semiconductor element disposed on the support with the epoxy resin composition according to any one of (1) to (11); a step of curing the epoxy resin composition; and a step of polishing a cured product of the epoxy resin composition.

### Effects of Invention

According to the present invention, there can be provided an epoxy resin composition capable of suppressing small pores generated when a surface of a cured product is polished, an electronic component using the epoxy resin composition, a semiconductor device using the epoxy resin composition, and a method for manufacturing the semiconductor device.

### BRIEF DESCRIPTION OF DRAWINGS

FIG. 1 is a SEM image of a surface of a cured product of an epoxy resin after second polishing in Example 1.

FIG. 2 is a SEM image of a surface of a cured product of an epoxy resin after second polishing in Comparative Example 1.

### DESCRIPTION OF EMBODIMENTS

### (Epoxy Resin Composition)

An epoxy resin composition according to an embodiment contains an epoxy resin, a curing accelerator, a filler, and an elastomer, preferably further contains a curing agent, and further contains other components as necessary.

### <Epoxy Resin>

The epoxy resin is not particularly limited as long as it is various epoxy resins generally used for semiconductor sealing, and can be appropriately selected according to the purpose. Examples thereof include an aliphatic epoxy resin and an aromatic epoxy resin. These may be used alone or in combination of two.

### <<Aliphatic Epoxy Resin>>

The aliphatic epoxy resin is contained in order to impart flexibility to a cured product of the epoxy resin composition (hereinafter, simply referred to as a “cured product”), and examples thereof include a monofunctional aliphatic epoxy resin, a bifunctional aliphatic epoxy resin, and a polyfunctional aliphatic epoxy resin. These may be used alone or in combination of two or more.

The monofunctional aliphatic epoxy resin is a compound having one epoxy group in the molecule, and examples thereof include alkyl alcohol glycidyl ethers such as butyl glycidyl ether and 2-ethylhexyl glycidyl ether and alkenyl alcohol glycidyl ethers such as vinyl glycidyl ether and allyl glycidyl ether.

The bifunctional aliphatic epoxy resin is a compound having two epoxy groups in the molecule, and examples thereof include alkylene glycol diglycidyl ether, poly(alkyleneglycol) diglycidyl ether, and alkenylene glycol diglycidyl ether.

The polyfunctional aliphatic epoxy resin is a compound having three or more epoxy groups in the molecule, and examples thereof include polyglycidyl ethers of tri- or higher functional alcohols such as trimethylolpropane, pentaerythritol, and dipentaerythritol of trimethylolpropane triglycidyl ether, pentaerythritol (tri or tetra)glycidyl ether, and dipentaerythritol (tri, tetra, penta or hexa)glycidyl ether.

The upper limit of the number of epoxy groups is not particularly limited and can be appropriately selected according to the purpose, but is preferably 5 or less.

Among them, the polyfunctional epoxy resin is preferable from the viewpoint of reliability (thermal cycle resistance) and the like.

The number average molecular weight of the aliphatic epoxy resin is not particularly limited and can be appropriately selected according to the purpose, but is preferably 200 to 2,000 from the viewpoint of imparting flexibility of the cured product of the epoxy resin composition.

As a method for measuring the number average molecular weight of the aliphatic epoxy resin, a general method for measuring the number average molecular weight can be used.

As the aliphatic epoxy resin, a synthesized product or a commercially available product may be used. Examples of the commercially available product include Epogosey PT (general grade) (manufactured by Yokkaichi Chemical Co., Ltd.), YX7400 (manufactured by Mitsubishi Chemical Corporation), SR-8EGS (manufactured by Sakamoto Yakuhin Kogyo Co., Ltd.), and PG-207GS (manufactured by Nippon Steel Chemical & Materials Co., Ltd.).

### <<Aromatic Epoxy Resin>>

Examples of the aromatic epoxy resin include glycidyl ethers of phenols, glycidyl ether esters of hydroxycarboxylic acids, monoglycidyl esters or polyglycidyl esters of carboxylic acids, glycidylamine-type epoxy resins, aminophenol-type epoxy resins, epoxy resins having a naphthalene skeleton, and novolak resins. These may be used alone or in combination of two or more.

Examples of the glycidyl ethers of phenols include bisphenol A, bisphenol F, bisphenol AD, bisphenol S, catechol, and resorcinol. As the glycidyl ethers of phenols, synthesized products or commercially available products may be used. Examples of the commercially available products include YDF8170 (manufactured by Nippon Steel Chemical & Materials Co., Ltd.), YDF870GS (manufactured by Nippon Steel Chemical & Materials Co., Ltd.), EXA-850CRP (manufactured by DIC Corporation), EXA-835LV (manufactured by DIC Corporation), and EP4005 (manufactured by ADEKA Corporation).

An example of the glycidyl ether esters of hydroxycarboxylic acids is p-hydroxybenzoic acid. As the glycidyl ether esters of hydroxycarboxylic acids, synthesized products or commercially available products may be used.

Examples of the monoglycidyl esters or polyglycidyl esters of carboxylic acids include benzoic acid, phthalic acid, and terephthalic acid. As the monoglycidyl esters or polyglycidyl esters of carboxylic acids, synthesized products or commercially available products may be used.

Examples of the glycidylamine-type epoxy resins include diglycidylaniline, diglycidyltoluidine, and tetraglycidyl-m-xylylenediamine. As the glycidylamine-type epoxy resins, synthesized products or commercially available products may be used. Examples of the commercially available products include EP3980S (manufactured by ADEKA Corporation) and ZX1059 (manufactured by Nippon Steel Chemical & Materials Co., Ltd.).

An example of the aminophenol-type epoxy resins is triglycidyl-p-aminophenol. As the aminophenol-type epoxy resins, synthesized products or commercially available products may be used. Examples of the commercially available products include jER630, jER630LSD (both manufactured by Mitsubishi Chemical Corporation), and EP3950L (manufactured by ADEKA Corporation).

Examples of the epoxy resins having a naphthalene skeleton include glycidyl ethers of naphthols and glycidyl ether esters of β-hydroxynaphthoic acids. As the epoxy resins having a naphthalene skeleton, synthesized products or commercially available products may be used. Examples of the commercially available products include HP4032, HP4032D, and HP4032SS (all manufactured by DIC Corporation).

Examples of the novolak resins include compounds obtained by novolakizing phenols such as phenol, catechol, and resorcinol. As the novolak resins, synthesized products or commercially available products may be used. An example of the commercially available products is jER152 (manufactured by Mitsubishi Chemical Corporation).

Among them, the epoxy resin is preferably a mixture of the aliphatic epoxy resin and the aromatic epoxy resin from the viewpoint of improving curability while maintaining the hardness of the cured product of the epoxy resin.

The ratio (mass ratio) of the aliphatic epoxy resin and the aromatic epoxy resin is not particularly limited and can be appropriately selected according to the purpose, but aliphatic epoxy resin:aromatic epoxy resin=20 mass % to 40 mass %: 60 mass % to 80 mass % is preferable.

### <Curing Accelerator>

The curing accelerator is contained in order to accelerate the crosslinking reaction between the epoxy resin and the epoxy resin and to increase the curing rate of the epoxy resin. In curing the epoxy resin composition, the curing accelerator is homopolymerized with the epoxy resin. That is, the curing accelerator does not remain in the crosslinked structure formed by the epoxy resin.

The curing accelerator is not particularly limited as long as it can cure the epoxy resin, and can be appropriately selected according to the purpose, but a heterocyclic compound containing a nitrogen atom is preferable from the viewpoint of reliability (thermal cycle resistance).

### <<Heterocyclic Compound Containing Nitrogen Atom>>

Examples of the heterocyclic compound containing a nitrogen atom include imidazole derivatives and microencapsulated heterocyclic compounds containing a nitrogen atom.

Examples of the imidazole derivatives include 2-methylimidazole, 2-undecylimidazole, 2-heptadecylimidazole, 2-ethyl-4-methylimidazole, 2-phenylimidazole, 2-phenyl-4-methylimidazole, 2-phenyl-4,5-dihydroxymethylimidazole, 2-phenyl-4-methyl-5-hydroxymethylimidazole, 1-cyanoethyl-2-undecylimidazole, 1-cyanoethyl-2-ethyl-4-imidazole, 2-phenylimidazole, 1-benzyl-2-phenylimidazole, benzimidazole, 2,4-diamino-6-[2′-methylimidazolyl-(1′)]ethyl-s-triazine, 2-phenyl-4,5-dihydroxymethylimidazole, and 2,3-dihydro-1H-pyrrolo[1,2-a]benzimidazole. These may be used alone or in combination of two or more.

As the imidazole derivatives, commercially available products or appropriately synthesized products may be used. Examples of the commercially available products include 2P4MZ (2-phenyl-4-methylimidazole), 2MZA (2,4-diamino-6-[2′-methylimidazolyl-(1′)]ethyl-s-triazine, 2-phenyl-4-methylimidazole) (both manufactured by SHIKOKU CHEMICALS CORPORATION), and the like.

As the microencapsulated nitrogen-containing heterocyclic compounds, commercially available products or appropriately synthesized products may be used. Examples of the commercially available products include Novacure HX3941HP, Novacure HXA3042HP, Novacure HXA3922HP, Novacure HXA3792, Novacure HX3748, Novacure HX3721, Novacure HX3722, Novacure HX3088, Novacure HX3741, Novacure HX3742, Novacure HX3613 (all manufactured by Asahi Kasei Corp.), Amicure PN-23J, Amicure PN-40J (both manufactured by Ajinomoto Fine-Techno Co., Inc.), and Fujicure FXR-1121 (manufactured by FUJIKASEI KOHGYOH CO., LTD). These may be used alone or in combination of two or more.

Among these nitrogen-containing heterocyclic compounds, 2-phenyl-4-methylimidazole and 2,4-diamino-6-[2′-methylimidazolyl-(1′)]ethyl-s-triazine are preferable from the viewpoint of reactivity and storage stability.

The content of the nitrogen-containing heterocyclic compound is not particularly limited and can be appropriately selected according to the purpose, but is preferably 2.0 mass % to 8.0 mass % and more preferably 2.5 mass % to 6.0 mass % with respect to the epoxy resin composition excluding the filler described later. When the content of the nitrogen-containing heterocyclic compound is 2.0 mass % or more, the curing time of the epoxy resin composition can be shortened, and the productivity of an electronic component device is improved. When the content of the nitrogen-containing heterocyclic compound is 8.0 mass % or less, the storage stability of the epoxy resin composition is improved.

Regarding the content of the microencapsulated nitrogen-containing heterocyclic compound, the active ingredient (nitrogen-containing heterocyclic compound) is preferably 3% by mass to 25% by mass and more preferably 5% by mass to 20% by mass with respect to the epoxy resin composition excluding the filler. When the content of the microencapsulated nitrogen-containing heterocyclic compound is 3 mass % or more, the curing time of the epoxy resin composition can be shortened, and the productivity of an electronic component device is improved. When the content of the microencapsulated nitrogen-containing heterocyclic compound is 25 mass % or less, the viscosity is not increased, and deterioration of workability can be prevented.

### <Filler>

The filler is contained in order to adjust the characteristics (mainly linear expansion coefficient, elastic modulus, and water absorption rate) of the cured product of the epoxy resin composition.

The filler is not particularly limited and can be appropriately selected according to the purpose, and examples thereof include silica such as fused silica or crystalline silica, calcium carbonate, clay, alumina, silicon nitride, silicon carbide, boron nitride, calcium silicate, potassium titanate, aluminum nitride, beryllia, zirconia, zircon, fosterite, steatite, spinel, mullite, titania, aluminum hydroxide, magnesium hydroxide, zinc borate, and zinc molybdate. These may be used alone or in combination of two or more. Among them, a silica filler and an alumina filler are preferable from the viewpoint of increasing the filling amount. As the filler, a synthesized product or a commercially available product may be used. Examples of the commercially available product include SE101G-SMO (manufactured by ADMATECHS COMPANY LIMITED), SE605G-SMG (manufactured by ADMATECHS COMPANY LIMITED), and STW7010-20 (manufactured by Nippon Steel Chemical & Materials Co., Ltd.) as the silica filler, and AG2051 SXM (manufactured by ADMATECHS COMPANY LIMITED) as the alumina filler.

The filler may be surface-treated. The surface treatment agent is not particularly limited and can be appropriately selected according to the purpose, and examples thereof include a silane coupling agent.

The silane coupling agent is not particularly limited and can be appropriately selected according to the purpose, and examples thereof include an epoxy-based silane coupling agent, a methacryl-based silane coupling agent, an amino-based silane coupling agent, a vinyl-based silane coupling agent, a glycidoxy-based silane coupling agent, and a mercapto-based silane coupling agent. Examples of the commercially available product include KBM403, KBE403, KBM503, and KBM573 (all manufactured by Shin-Etsu Chemical Co., Ltd.).

The volume average particle diameter of the filler is not particularly limited and can be appropriately selected according to the purpose, but is preferably 0.1 μm to 15.0 μm and more preferably 0.3 μm to 10.0 μm.

In the present embodiment, the volume average particle diameter refers to a particle diameter at 50% in a volume cumulative particle size distribution measured using a laser diffraction method is.

The shape of the filler is not particularly limited and can be appropriately selected according to the purpose, and examples thereof include a spherical shape, an amorphous shape, and a flaky shape.

The content of the filler is preferably 73.0 mass % to 87.5 mass % and more preferably 75.0 mass % to 85.0 mass % from the viewpoint of reduction of the linear expansion coefficient of the cured product of the epoxy resin composition, and workability. When the content of the filler is 73.0 mass % or less, the linear expansion coefficient of the cured product of the epoxy resin composition increases, and warpage may increase. When the content of the filler is 87.5 mass % or more, the viscosity of the epoxy resin composition increases, so that the workability may be deteriorated.

### <Elastomer>

The elastomer is contained in order to impart injectability to the epoxy resin composition and to improve the adhesive strength of the cured product of the epoxy resin composition.

The elastomer is at least one selected from a solid elastomer having a structure having no double bond in the main chain and a liquid elastomer from the viewpoint of suppressing small pores generated when the surface of the cured product is polished. These may be used alone or in combination of two.

When the surface of a cured product of a conventional epoxy resin composition containing an elastomer is polished, small pores may be generated. There are mainly three reasons for this. The first is falling off of the elastomer portion present in the cured product of the epoxy resin composition. In general, a cured product of an elastomer has high abrasion resistance. Therefore, when the cured product of the epoxy resin composition is polished, the portion of the elastomer in the cured product of the epoxy resin composition is polished together with the portion of the epoxy resin, the filler, or the like, and falls off from the surface of the cured product of the epoxy resin composition. The falling elastomer portion becomes a small pore. The second is falling off of the filler present in the cured product of the epoxy resin composition. Depending on the polishing conditions, the filler falls off without being polished similarly to the elastomer portion described above. The third is damage to the polished surface of the cured product of the epoxy resin composition. Depending on the polishing conditions, the surface of the cured product of the epoxy resin composition is not polished but subjected to a physical impact to form a small pore.

Therefore, in the present embodiment, an elastomer having low abrasion resistance is used in the elastomer. It is considered that by using such an elastomer, small pores generated when the surface of the cured product is polished can be suppressed.

### <<Solid Elastomer>

The solid elastomer is an elastomer that is solid at normal temperature (25° C.) and a structure having no double bond in the main chain. An example of the elastomer having a structure having no double bond in the main chain is silicone. Silicone has a siloxane bond, and the abrasion resistance of the surface by polishing or the like is low, so that it is possible to suppress small pores generated when the surface of the cured product is polished and flattened.

The solid elastomer is preferably a core-shell type elastomer from the viewpoint of compatibility with the epoxy resin. The core-shell type refers to a type in which the outer side of a core (nucleus) is covered with a material different from the core.

The core-shell type elastomer used in the embodiment is preferably an elastomer using a silicone resin for the core and an acrylic copolymer for the shell from the viewpoint of exhibiting a low elastic modulus in a temperature range in which the epoxy resin composition is used and being capable of reducing the shrinkage stress of the epoxy resin composition.

When the epoxy resin composition is produced using the core-shell type elastomer, the core-shell type elastomer may be mixed at the same time when the respective components of the epoxy resin composition are mixed, but it is preferable to produce the epoxy resin composition by performing a masterbatch treatment in which the core-shell type elastomer is dispersed in the epoxy resin in advance and then mixed, and thereafter mixing other components of the epoxy resin composition.

### <<Liquid Elastomer>>

The liquid elastomer is also referred to as a liquid-like elastomer and is an elastomer that is liquid at normal temperature (25° C.). The liquid elastomer is not particularly limited and can be appropriately selected according to the purpose, and an example thereof is a copolymer of butadiene and acrylonitrile (butadiene-acrylonitrile copolymer).

The content of the elastomer is preferably 5.0 mass % or more, more preferably 5.0 mass % to 20.0 mass %, and still more preferably 8.0 mass % to 17.0 mass % with respect to components of the epoxy resin composition excluding the filler. When the content of the elastomer is within this range, the adhesive strength can be improved, and deterioration of workability due to high viscosity can be prevented.

### <Curing Agent>

The curing agent is contained in order to cure the epoxy resin. In curing the epoxy resin composition, the curing agent is addition-polymerized with the epoxy resin. That is, the curing agent enters the crosslinked structure formed by the epoxy resin.

The curing agent is not particularly limited as long as it can cure the epoxy resin, and can be appropriately selected according to the purpose. Examples thereof include a phenolic curing agent, an amine-based curing agent, and an acid anhydride-based curing agent. These may be used alone or in combination of two or more.

The content of the curing agent is not particularly limited and can be appropriately selected according to the purpose, but the stoichiometric equivalent ratio with the epoxy resin (curing agent equivalent/epoxy group equivalent) is preferably 0.01 to 1.00, more preferably 0.01 to 0.50, and still more preferably 0.08 to 0.30.

The content of the curing agent is not particularly limited and can be appropriately selected according to the purpose, but is preferably 0.5 mass % to 2.0 mass % and more preferably 0.5 mass % to 1.0 mass %.

### <Other Components>

Other components are not particularly limited as long as they are used in a normal epoxy resin composition, and can be appropriately selected according to the purpose. Examples thereof include: colorants such as a coupling agent, a dye, a pigment, and carbon black; silicone oil; surfactants; antioxidants; conventionally known flame retardants such as antimony oxides (such as antimony trioxide, antimony tetraoxide, and antimony pentoxide) and brominated epoxy resins, ion trapping agents; leveling agents; antifoaming agents; and reactive diluents. These may be used alone or in combination of two or more.

The content of other components is not particularly limited and can be appropriately selected according to the purpose.

### <Physical Properties of Epoxy Resin Composition>

### <<Viscosity>>

The viscosity at 25° C. of the epoxy resin composition in the embodiment is preferably 1,000 Pa's or less, more preferably 700 Pa's or less, and still more preferably 500 Pa's or less. From the viewpoint of handling, the viscosity at 25° C. of the epoxy resin composition is preferably 150 Pa's or more.

In the present specification, the viscosity is measured at a rotation speed of 10 rpm using an HB-DV type viscometer.

### <<Thermal Time Viscosity (Viscosity at 120° C.)>>

The viscosity at 120° C. of the epoxy resin composition in the embodiment is preferably 0.5 Pas to 40.0 Pa·s.

The viscosity at 120° C. can be measured using a rheometer.

### <Physical Properties of Cured Product of Epoxy Resin Composition>

In the cured product of the epoxy resin composition according to the embodiment, the number of small pores after the surface of the cured product is polished by the first polishing and the second polishing is 10 or less per predetermined area.

Here, the small pore is a pore having a diameter of 0.05 μm to 0.5 μm among the pores on the surface of the cured product after polishing. The diameter indicates the maximum length of a line connecting two points on the outer periphery of the small pore, and the same applies to a case where the pore is not a perfect circle but an ellipse.

The depth of the pore is 0.03 μm to 0.3 μm.

### <<First Polishing>>

The first polishing is performed by roughly polishing (grinding) the surface of the cured product. Specifically, water-resistant abrasive paper is used. Examples of the abrasive grain size of the abrasive paper include #600, #800, and #1200. An example of the polishing conditions for forming the polished surface by the first polishing is the following conditions.

The surface of the cured product is subjected to a polishing treatment under the following conditions by using a Struers automatic polisher (Tegramin-20, manufactured by Struers LLC).
Polishing member: water-resistant abrasive paper #600
Polishing time: 3 minutes

The rotation speed and the polishing load are as follows.
Rotation speed: 150 rpm
Polishing load: 10 N

### <<Second Polishing>>

The second polishing is performed with a liquid containing a polishing agent after the first polishing. An example of the liquid containing a polishing agent is a liquid in which abrasive grains are dispersed in water. In addition, the liquid containing a polishing agent may be a polishing agent slurry. The second polishing is specifically chemical mechanical polishing (CMP), i.e., polishing with a polishing pad and a polishing slurry. An example of the polishing conditions for forming the polished surface by the second polishing is the following conditions.

The surface of the cured product is subjected to a polishing treatment under the following conditions in the order from step 1 to step 3 using a Struers automatic polisher (Tegramin-20, manufactured by Struers LLC).

### Step 1

Polishing member: diamond slurry (6-PC, 6p slurry (particle size range: 4 μm to 8 μm) manufactured by ENGIS JAPAN CORPORATION)
Polishing time: 6 minutes

### Step 2

Polishing member: diamond slurry (1-PC, 1μ slurry (particle size range: 0 μm to 2 μm) manufactured by ENGIS JAPAN CORPORATION)
Polishing time: 3 minutes

### Step 3

Polishing member: diamond slurry (Master prep manufactured by BUEHLER, average particle diameter: 0.05 μm)
Polishing time: 2 minutes

The rotation speed and the polishing load in steps 1 to 3 are as follows.
Rotation speed: 150 rpm
Polishing load: 10 N

The arithmetic average roughness Ra of the polished surface of the cured product after the second polishing is preferably 500 nm or less, more preferably 300 nm or less, and still more preferably 100 nm or less. The lower limit of the arithmetic average roughness Ra of the polished surface is not particularly limited and is, for example, 10 nm or more or 20 nm or more.

The arithmetic surface roughness Ra of the polished surface can be calculated, for example, by a method specified in JIS B 0601:2001, using a confocal scanning electron microscope (OPTELICS H1200, manufactured by Lasertec Corporation) to measure the surface of the cured product of the epoxy resin composition after the second polishing.

The number of small pores on the surface of the cured product of the epoxy resin composition polished by the first polishing and the second polishing can be measured by observing the surface with a scanning electron microscope (SEM) at a magnification of 5,000. The predetermined area mentioned above refers to one field of view in SEM observation and is about 3.9 μm².

In SEM observation, the gradation of the obtained image is determined according to the height of the electron density. That is, the gradation in the SEM image is determined depending on the type of the compound.

### <Method for Manufacturing Epoxy Resin Composition>

The method for producing the epoxy resin composition according to the embodiment is not particularly limited and can be appropriately selected according to the purpose, and an example thereof is a method of mixing and stirring the above components.

When the epoxy resin is solid, the epoxy resin is preferably liquefied by heating or the like, fluidized, and then mixed.

The components may be mixed simultaneously, or some components may be mixed first, and the remaining components may be mixed later. When it is difficult to uniformly disperse the filler in the epoxy resin, the epoxy resin and the filler may be mixed first, and the remaining components may be mixed later.

The apparatus used for mixing and stirring is not particularly limited and can be appropriately selected according to the purpose, and examples thereof include a roll mill, a ball mill, a planetary mixer, a bead mill, a Henschel mixer, and a grinding mixer equipped with a stirrer and a heater.

### <Applications of Epoxy Resin Composition>

Since the epoxy resin composition according to the embodiment is an epoxy resin composition capable of suppressing small pores generated when the surface of the cured product is polished, it can be suitably used as a liquid compression molding material.

### (Electronic Component)

The electronic component according to the present embodiment includes a support and a cured product of the epoxy resin composition.

Examples of the electronic component include a semiconductor element and a support sealed with an epoxy resin composition.

### <Support>

The support is not particularly limited as long as it can fix the semiconductor element, and can be appropriately selected according to the purpose. An example thereof is a substrate.

### <<Substrate>>

The substrate is not particularly limited and can be appropriately selected according to the purpose, and examples thereof include a lead frame, a wired tape carrier, a wiring board, glass, and a silicon wafer.

The size, shape, and material of the substrate are not particularly limited as long as the substrate is used as a normal substrate, and can be appropriately selected according to the purpose.

### <Semiconductor Element>

The semiconductor element is not particularly limited and can be appropriately selected according to the purpose, and is, for example, an active element such as a semiconductor chip, a transistor, a diode, or a thyristor, and a passive element such as a capacitor, a resistor, a resistor array, a coil, or a switch.

The size, shape, and material of the semiconductor element are not particularly limited as long as the semiconductor element is used as a normal semiconductor element, and can be appropriately selected according to the purpose.

The cured product of the epoxy resin composition is provided between the support and the semiconductor element.

The thickness of the cured product of the epoxy resin composition is not particularly limited and can be appropriately selected according to the purpose, and is, for example, 10 μm or more and 800 μm or less.

The shape of the cured product of the epoxy resin composition is not particularly limited and can be appropriately selected according to the purpose.

### (Semiconductor Device)

The semiconductor device (semiconductor package) according to the present embodiment includes the above-described electronic component and further includes other members as necessary.

The other members are not particularly limited and can be appropriately selected according to the purpose.

### (Method for Manufacturing Semiconductor Device)

The method for manufacturing a semiconductor device according to the present embodiment includes a step of filling with an epoxy resin composition, a step of curing the epoxy resin composition, and a step of polishing a cured product of the epoxy resin composition, and further includes other steps as necessary.

<Step of Filling with Epoxy Resin Composition>

The step of filling with the epoxy resin composition is a step of filling a void between a support and a semiconductor element disposed on the support with the epoxy resin composition. The method for filling with the epoxy resin composition is not particularly limited and can be appropriately selected according to the purpose, and examples thereof include a dispensing method, a casting method, and a printing method.

The amount of the epoxy resin composition to be filled with is not particularly limited and can be appropriately selected according to the purpose, and an example thereof is an amount such that the thickness of the cured product of the epoxy resin composition is 10 μm or more and 800 μm or less.

### <Step of Curing Epoxy Resin Composition>

The step of curing the epoxy resin composition is a step of curing the epoxy resin composition between the support and the semiconductor element.

The method for curing the epoxy resin composition is not particularly limited and can be appropriately selected according to the purpose, and examples thereof include a method of heating and curing the support, the epoxy resin composition, and the semiconductor element while compressing them under reduced pressure (compression molding), a method of heating and curing the dispensed epoxy resin composition in a dryer, and a method of heating and curing the epoxy resin composition subjected to stencil printing in a dryer.

### <Step of Polishing Cured Product of Epoxy Resin Composition>

The step of polishing the cured product of the epoxy resin composition is a step of polishing the surface of the obtained cured product of the epoxy resin composition to flatten the surface of the cured product.

The polishing method is not particularly limited and can be appropriately selected according to the purpose, and examples thereof include the first polishing method and the second polishing method described above.

### <Other Steps>

Other steps are not particularly limited and can be appropriately selected according to the purpose, and examples thereof include a step of disposing a semiconductor element on a support and a rewiring layer forming step.

### EXAMPLES

### Examples 1 to 13 and Comparative Examples 1 to 4

Epoxy resin compositions were prepared according to the formulations shown in Tables 1 to 4. An epoxy resin, a curing accelerator, a filler, an elastomer, a curing agent, and a coupling agent were weighed, dispersed with a ceramic three-roll mill (manufactured by INOUE MFG., INC.), and formed into a paste to prepare an epoxy resin composition.

The numerical values in the tables represent parts by mass unless otherwise specified.

TABLE 1

| | | Examples | | | |
|---|---|---|---|---|---|
| | | 1 | 2 | 3 | 4 |
| Epoxy resin | Bisphenol F type epoxy resin | 34.6 | 31.3 | 31.3 | 31.3 |
| | Aminophenol type | 33.4 | 33.8 | 33.8 | 33.8 |
| | epoxy resin | | | | |
| | Aliphatic epoxy resin | 32.0 | 34.9 | 34.9 | 34.9 |
| Curing | 2-Phenyl-4-methylimidazole | 4.0 | 4.0 | 4.0 | 4.0 |
| accelerator | 2,4-Diamino-6-[2′- | — | — | — | — |
| | methylimidazolyl- | | | | |
| | (1′)]-ethyl-s-triazine | | | | |
| | Imidazole compound | — | — | — | — |
| Filler | Silica filler 1 | 452.0 | 409.6 | 409.6 | 409.6 |
| | Silica filler 2 | — | — | — | — |
| Elastomer | Silicone-based rubber | 13.0 | — | — | 6.5 |
| | (core-shell type) | | | | |
| | Silicone composite powder | — | 13.0 | — | — |
| | Butadiene-acrylonitrile | — | — | 13.0 | 6.5 |
| | copolymer | | | | |
| | Butadiene-based rubber | — | — | — | — |
| | (core-shell type) | | | | |
| | Polybutyl acrylate- | — | — | — | — |
| | based rubber | | | | |
| | (core-shell type) | | | | |
| | Silicone-acryl composite | — | — | — | — |
| | rubber | | | | |
| | Acrylic rubber | — | — | — | — |
| | (core-shell type) | | | | |
| Curing Agent | Phenolic curing agent | — | — | — | — |
| | Amine-based curing agent | — | — | — | — |
| | Acid anhydride-based | — | — | — | — |
| | curing agent | | | | |
| Other | Coupling agent | 1.4 | — | — | — |
| Total (parts by mass) | | 570.4 | 526.6 | 526.6 | 526.6 |
| Filler content (mass %) | | 79.2 | 77.8 | 77.8 | 77.8 |
| Elastomer content (mass %) | | 11.0 | 11.1 | 11.1 | 11.1 |
| Evaluation | Viscosity (Pa · s) | 160 | 430 | 170 | 230 |
| result | Evaluation of viscosity | A | A | A | A |
| | Thermal time viscosity (Pa · s) | 1.4 | 1.8 | 1.6 | 1.6 |
| | Adhesive strength (MPa) | 8.2 | 7.5 | 6 | 6.5 |
| | Evaluation of adhesive strength | A | B | B | B |
| | Number of pores on surface | A | A | A | A |
| | after polishing | | | | |
| | Surface roughness Ra (nm) | 62 | 65 | 75 | 69 |

TABLE 2

| | | Examples | | | |
|---|---|---|---|---|---|
| | | 5 | 6 | 7 | 8 |
| Epoxy resin | Bisphenol F type epoxy resin | 31.3 | 74.4 | 31.3 | 31.3 |
| | Aminophenol type | 33.9 | — | 33.8 | 33.8 |
| | epoxy resin | | | | |
| | Aliphatic epoxy resin | 34.8 | 25.6 | 34.9 | 34.9 |
| Curing | 2-Phenyl-4-methylimidazole | 4.0 | 4.0 | — | — |
| accelerator | 2,4-Diamino-6-[2′- | — | — | 4.0 | — |
| | methylimidazolyl- | | | | |
| | (1′)]-ethyl-s-triazine | | | | |
| | Imidazole compound | — | — | — | 4.0 |
| Filler | Silica filler 1 | 392.4 | 392.4 | 409.6 | 409.6 |
| | Silica filler 2 | — | — | — | — |
| Elastomer | Silicone-based rubber | 6.0 | 25.0 | 13.0 | 13.0 |
| | (core-shell type) | | | | |
| | Silicone composite powder | — | — | — | — |
| | Butadiene-acrylonitrile | — | — | — | — |
| | copolymer | | | | |
| | Butadiene-based rubber | — | — | — | — |
| | (core-shell type) | | | | |
| | Polybutyl acrylate- | — | — | — | — |
| | based rubber | | | | |
| | (core-shell type) | | | | |
| | Silicone-acryl composite | — | — | — | — |
| | rubber | | | | |
| | Acrylic rubber | — | — | — | — |
| | (core-shell type) | | | | |
| Curing Agent | Phenolic curing agent | — | — | — | — |
| | Amine-based curing agent | — | — | — | — |
| | Acid anhydride-based | — | — | — | — |
| | curing agent | | | | |
| Other | Coupling agent | — | — | — | — |
| Total (parts by mass) | | 502.4 | 521.4 | 526.6 | 526.6 |
| Filler content (mass %) | | 78.1 | 75.3 | 77.8 | 77.8 |
| Elastomer content (mass %) | | 5.5 | 19.4 | 11.1 | 11.1 |
| Evaluation | Viscosity (Pa · s) | 70 | 750 | 240 | 340 |
| result | Evaluation of viscosity | A | A | A | A |
| | Thermal time viscosity (Pa · s) | 0.6 | 2.6 | 1.7 | 2 |
| | Adhesive strength (MPa) | 6.2 | 9.2 | 8.4 | 8.1 |
| | Evaluation of adhesive strength | B | A | A | A |
| | Number of pores on surface | A | A | A | A |
| | after polishing | | | | |
| | Surface roughness Ra (nm) | 68 | 67 | 71 | 73 |

TABLE 3

| | | Examples | | | | |
|---|---|---|---|---|---|---|
| | | 9 | 10 | 11 | 12 | 13 |
| Epoxy resin | Bisphenol F type epoxy resin | 34.6 | 34.6 | 34.6 | 34.6 | 34.6 |
| | Aminophenol type epoxy resin | 33.4 | 33.4 | 33.4 | 33.4 | 33.4 |
| | Aliphatic epoxy resin | 32.0 | 32.0 | 32.0 | 32.0 | 32.0 |
| Curing | 2-Phenyl-4-methylimidazole | 4.0 | 4.0 | 4.0 | 4.0 | 4.0 |
| accelerator | 2,4-Diammo-6-[2′- | — | — | — | — | — |
| | methylimidazolyl-(1′)]- | | | | | |
| | ethyl-s-triazine | | | | | |
| | Imidazole compound | — | — | — | — | — |
| Filler | Silica filler 1 | 452.0 | 452.0 | 452.0 | — | 662.7 |
| | Silica filler 2 | — | — | — | 414.0 | — |
| Elastomer | Silicone-based rubber | 13.0 | 13.0 | 13.0 | 13.0 | 13.0 |
| | (core-shell type) | | | | | |
| | Silicone composite powder | — | — | — | — | — |
| | Butadiene-acrylonitrile | — | — | — | — | — |
| | copolymer | | | | | |
| | Butadiene-based rubber | — | — | — | — | — |
| | (core-shell type) | | | | | |
| | Polybutyl acrylate-based | — | — | — | — | — |
| | rubber (core-shell type) | | | | | |
| | Silicone-acryl composite | — | — | — | — | — |
| | rubber | | | | | |
| | Acrylic rubber | — | — | — | — | — |
| | (core-shell type) | | | | | |
| Curing Agent | Phenolic curing agent | 7.7 | — | — | — | — |
| | Amine-based curing agent | — | 7.7 | — | — | — |
| | Acid anhydride-based | — | — | 7.7 | — | — |
| | curing agent | | | | | |
| Other | Coupling agent | — | — | — | — | — |
| Total (parts by mass) | | 576.7 | 576.7 | 576.7 | 531.0 | 779.7 |
| Filler content (mass %) | | 78.4 | 78.4 | 78.4 | 78.0 | 85.0 |
| Elastomer content (mass %) | | 10.4 | 10.4 | 10.4 | 11.1 | 11.1 |
| Evaluation | Viscosity (Pa · s) | 690 | 780 | 840 | 450 | 930 |
| result | Evaluation of viscosity | A | A | A | A | A |
| | Thermal time viscosity (Pa · s) | 8.2 | 6.5 | 7.1 | 1.4 | 2.8 |
| | Adhesive strength (MPa) | 8.4 | 8.3 | 8.7 | 7.6 | 8.5 |
| | Evaluation of adhesive strength | A | A | A | B | A |
| | Number of pores on surface | A | A | A | A | A |
| | after polishing | | | | | |
| | Surface roughness Ra (nm) | 62 | 64 | 68 | 71 | 68 |

TABLE 4

| | | Comparative Examples | | | |
|---|---|---|---|---|---|
| | | 1 | 2 | 3 | 4 |
| Epoxy resin | Bisphenol F type epoxy resin | 31.1 | 31.3 | 31.3 | 31.3 |
| | Aminophenol type | 33.9 | 33.8 | 33.8 | 33.8 |
| | epoxy resin | | | | |
| | Aliphatic epoxy resin | 35.0 | 34.9 | 34.9 | 34.9 |
| Curing | 2-Phenyl-4-methylimidazole | 4.0 | 4.0 | 4.0 | 4.0 |
| accelerator | 2,4-Diamino-6-[2′- | — | — | — | — |
| | methylimidazolyl- | | | | |
| | (1′)]-ethyl-s-triazine | | | | |
| | Imidazole compound | — | — | — | — |
| Filler | Silica filler 1 | 468.6 | 409.6 | 409.6 | 409.6 |
| | Silica filler 2 | — | — | — | — |
| Elastomer | Silicone-based rubber | — | — | — | — |
| | (core-shell type) | | | | |
| | Silicone composite powder | — | — | — | — |
| | Butadiene-acrylonitrile | — | — | — | — |
| | copolymer | | | | |
| | Butadiene-based rubber | 13.0 | — | — | — |
| | (core-shell type) | | | | |
| | Polybutyl acrylate- | — | 13.0 | — | — |
| | based rubber | | | | |
| | (core-shell type) | | | | |
| | Silicone-acryl composite | — | — | 13.0 | — |
| | rubber | | | | |
| | Acrylic rubber | — | — | — | 13.0 |
| | (core-shell type) | | | | |
| Curing Agent | Phenolic curing agent | — | — | — | — |
| | Amine-based curing agent | — | — | — | — |
| | Acid anhydride-based | — | — | — | — |
| | curing agent | | | | |
| Other | Coupling agent | — | — | — | — |
| Total (parts by mass) | | 587.0 | 526.6 | 526.6 | 526.6 |
| Filler content (mass %) | | 79.8 | 77.8 | 77.8 | 77.8 |
| Elastomer content (mass %) | | 11.0 | 11.1 | 11.1 | 11.1 |
| Evaluation | Viscosity (Pa · s) | 260 | 320 | 830 | 910 |
| result | Evaluation of viscosity | A | A | A | A |
| | Thermal time viscosity (Pa · s) | 1.5 | 1.7 | 3.4 | 3.9 |
| | Adhesive strength (MPa) | 9.7 | 8.3 | 7.8 | 7.2 |
| | Evaluation of adhesive strength | A | A | B | B |
| | Number of pores on surface | B | B | B | B |
| | after polishing | | | | |
| | Surface roughness Ra (nm) | 91 | 95 | 93 | 89 |

The epoxy resins used in Examples and Comparative Examples are as follows.
Bisphenol F type epoxy resin (YDF8170, epoxy equivalent: 158 g/eq, manufactured by NIPPON STEEL Chemical & Material Co., Ltd.)
Aminophenol type epoxy resin (jER 630, epoxy equivalent: 98 g/eq, manufactured by Mitsubishi Chemical Corporation)
Aliphatic epoxy resin (EPOGOSEY PT (general grade), epoxy equivalent: 435 g/eq, manufactured by Yokkaichi Chemical Co., Ltd.)

The curing accelerators used in Examples and Comparative Examples are as follows.
2-Phenyl-4-methylimidazole (2P4MZ manufactured by Shikoku Chemicals Corporation)
2,4-Diamino-6-[2′-methylimidazolyl-(1′)]-ethyl-s-triazine (2MZA manufactured by Shikoku Chemicals Corporation)
Imidazole compound (2P4MHZ manufactured by Shikoku Chemicals Corporation)

The fillers used in Examples and Comparative Examples are as follows.
Silica filler 1 (SE605G-SMG, 3-methacryloxypropyltrimethoxysilane surface-treated, average particle diameter: 1.8 μm, top cut diameter: 5 μm, manufactured by Admatechs Co., Ltd.)
Silica filler 2 (SE101G-SMO, 3-methacryloxypropyltrimethoxysilane surface-treated, average particle diameter: 0.3 μm, top cut diameter: 1 μm, manufactured by Admatechs Co., Ltd.)

The elastomers used in Examples and Comparative Examples are as follows.
Silicone-based rubber (core-shell type) (core-shell type silicone-based rubber particles, MX-965, manufactured by KANEKA CORPORATION, elastomer component: 25%)
Silicone composite powder (KMP605, manufactured by Shin-Etsu Chemical Co., Ltd., elastomer component: 100%)
Butadiene-acrylonitrile copolymer (carboxyl-terminated butadiene-acrylonitrile copolymer, CTBN1008SP, manufactured by Chori GLEX Co., Ltd., elastomer component: 100%)
Butadiene-based rubber (core-shell type) (core-shell type butadiene-based rubber particles, MX-137, manufactured by KANEKA CORPORATION, elastomer component: 33%)
Polybutyl acrylate-based rubber (core-shell type) (core-shell type polybutyl acrylate-based rubber particles, ALBIDURE EP XP powder, manufactured by Evonik Industries AG, elastomer component: 100%)
Silicone-acryl composite rubber (METABLEN S-2501, manufactured by Mitsubishi Chemical Corporation, elastomer component: 100%)
Acrylic rubber (core-shell type) (core-shell type acrylic rubber particles, STAPHYLOID AC3355, manufactured by Aica Kogyo Company, Limited, elastomer component: 100%)

The curing agents used in Examples and Comparative Examples are as follows.
Phenolic curing agent (MEH-8005, hydroxyl equivalent: 139 g/eq. to 143 g/eq., manufactured by Meiwa Plastic Industries, Ltd.)
Amine-based curing agent (ETHACURE 100PLUS manufactured by Albemarle Corporation)
Acid anhydride-based curing agent (HN-2200 manufactured by Showa Denko Materials Co., Ltd.)

Other components used in Examples and Comparative Examples are as follows.
Coupling agent (3-isocyanate propyltriethoxysilane, KBE-9007, manufactured by Shin-Etsu Chemical Co., Ltd.)

The viscosity, the thermal time viscosity, the adhesive strength, the number of pores on the surface after polishing, and the surface roughness of the obtained epoxy resin composition were measured and evaluated. The measurement result and the evaluation result are shown in Tables 1 to 4.

### <Viscosity and Thermal Time Viscosity>

Using an HB-DV type viscometer (HB-DVI, manufactured by Brookfield), the viscosity of each epoxy resin composition immediately after preparation was measured at a liquid temperature of 25° C. at 10 rpm or 5 rpm and evaluated based on the following evaluation criteria.

### —Evaluation Criteria—

A: Viscosity is 1,000 Pa's or less.
B: Viscosity is more than 1,000 Pas.

In addition, the thermal time viscosity at 120° C. was measured using a rheometer (MARS III, manufactured by HAAKE). Each epoxy resin composition (0.3 mL+0.1 mL) was put on a plate heated to 120° C., and measurement was started at a measurement frequency of 10 Hz, a strain amount of 0.5, a gap of 0.5 mm, and a measurement interval of 1 second. The thermal time viscosity after 40 seconds was measured, and the measurement result was taken as the thermal time viscosity at 120° C.

### <Adhesive Strength>

Each epoxy resin composition was bonded onto a 10 mm square silicon chip using a mold so as to have a truncated cone shape with a bottom surface diameter of 5 mm, a top surface diameter of 3 mm, and a height of 6 mm, and cured at 150° C. for 2 hours to prepare a test piece. The resin portion of the test piece was flicked by a bond tester (Dage 4000, manufactured by Nordson Advanced Technology Inc.) to measure the shear adhesive strength.

From the value of the shear adhesive strength, the adhesive strength was evaluated based on the following evaluation criteria.

### —Evaluation Criteria—

A: Shear adhesive strength is 8 MPa or more.
B: Shear adhesive strength is 6 MPa or more and less than 8 MPa.
C: Shear adhesive strength is less than 6 MPa.
   <Number of Pores on Surface after Polishing>

Each epoxy resin composition was compression molded on a 12 inch silicon wafer so as to have a thickness of 300 μm. Thereafter, the silicon wafer was divided into about 50 pieces, and the surface of the cured product of the epoxy resin composition on each of the pieces was polished by the first polishing method and then polished by the second polishing method.

The first polishing method is polishing with water-resistant abrasive paper (#600) using a polisher (Tegramin-20, manufactured by Struers LLC). In the polishing, the polishing time was 3 minutes, the rotation speed was 150 rpm, and the polishing load was 10 N.

The second polishing method is polishing performed in the order of steps 1 to 3 described below using a polisher (Tegramin-20, manufactured by Struers LLC).

### Step 1

Polishing member: diamond slurry (6-PC, 6μ slurry (particle size range: 4 μm to 8 μm) manufactured by ENGIS JAPAN CORPORATION)
Polishing time: 6 minutes

### Step 2

Polishing member: diamond slurry (1-PC, 1μ slurry (particle size range: 0 μm to 2 μm) manufactured by ENGIS JAPAN CORPORATION)
Polishing time: 3 minutes

### Step 3

Polishing member: diamond slurry (Master prep manufactured by BUEHLER, average particle diameter: 0.05 μm)
Polishing time: 2 minutes

The rotation speed and the polishing load in steps 1 to 3 are as follows.
Rotation speed: 150 rpm
Polishing load: 10 N

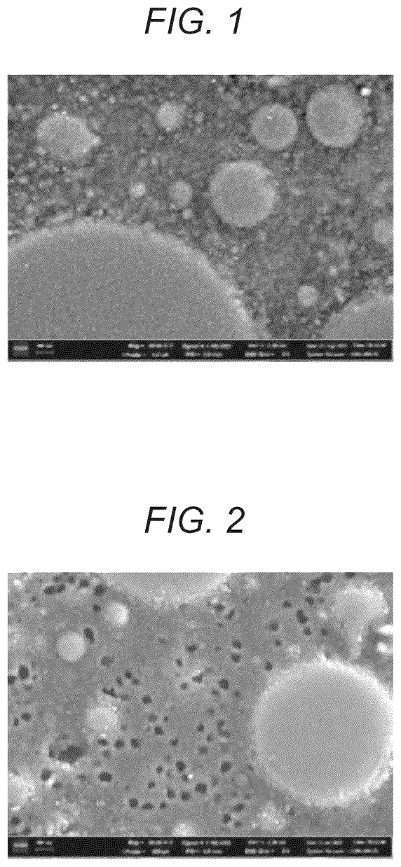

The surface of the cured product of the epoxy resin composition after polishing was observed by a SEM (MERLIN, manufactured by ZEISS) at a magnification of 50,000 times, the number of pores having a diameter of 0.05 μm to 0.50 μm present in one field of view was counted, and the surface state after polishing was evaluated based on the following evaluation criteria. FIG. 1 is an image of SEM observation of Example 1, and FIG. 2 is a SEM image of Comparative Example 1.

The area of one field of view in SEM observation at 50,000 times is about 3.9 μm².

### —Evaluation Criteria—

A: The number of pores of 0.05 μm to 0.50 μm on the polished surface is 9 or less.
B: The number of pores of 0.05 μm to 0.50 μm on the polished surface is 10 or more.

### <Measurement of Surface Roughness (Ra)>

The Ra was calculated by a method specified in JIS B 0601:2001, using a confocal scanning electron microscope (OPTELICS H1200, manufactured by Lasertec Corporation) to measure the surface of the cured product of the epoxy resin composition after the second polishing.

The measurement conditions were as follows. The scan width was set to 100 μm, the scan type was set to an area, the light source was set to Blue, the cutoff value was set to ⅕, the object lens was set to ×100, the contact lens was set to ×14, the digital zoom was set to ×1, and the Z pitch was set to 10 nm. The Ra value was measured at three locations, and an average value thereof was taken.

As shown in Tables 1 to 4, all of the epoxy resin compositions of Examples were evaluated as “A” for the number of pores on the surface after polishing. These epoxy resin compositions were epoxy resin compositions capable of suppressing small pores generated when the surface of the cured product is polished.

On the other hand, all of Comparative Examples 1 to 4, in which a solid elastomer having a double bond in the main chain was used as the elastomer, were evaluated as “B” for the number of pores on the surface after polishing. From these facts, it has become clear that an epoxy resin composition containing as the elastomer a solid elastomer having no double bond in the main chain or a liquid elastomer can suppress small pores generated when the surface of the cured product is polished.

Although the embodiments and examples of the present invention have been described, these are presented as examples and are not intended to limit the scope of the invention. The embodiments can be implemented in various other forms, and various omissions, substitutions, and changes can be made without departing from the gist of the invention. The embodiments and modifications thereof are included in the scope and gist of the invention and are included in the invention described in the claims and the equivalent scope thereof.

1. An epoxy resin composition comprising an epoxy resin, a curing accelerator, a filler, and an elastomer, wherein
the elastomer is at least one selected from a solid elastomer and a liquid elastomer, and
the solid elastomer has a structure having no double bond in a main chain.

2. The epoxy resin composition according to claim 1, wherein after a surface of a cured product of the epoxy resin composition is polished by first polishing for rough polishing and second polishing for polishing with a liquid containing a polishing agent, the number of pores having a diameter of 0.05 μm to 0.5 μm present on a surface of the cured product is 10 or less per predetermined area.

3. The epoxy resin composition according to claim 1, wherein a content of the elastomer is 5.0 mass % or more with respect to components of the epoxy resin composition excluding the filler.

4. The epoxy resin composition according to claim 1, wherein the solid elastomer is a core-shell type.

5. The epoxy resin composition according to claim 1, wherein a content of the elastomer is 5.0 mass % to 20.0 mass % with respect to components of the epoxy resin composition excluding the filler.

6. The epoxy resin composition according to claim 1, wherein a content of the filler is 73.0 mass % to 87.5 mass %.

7. The epoxy resin composition according to claim 1, having a viscosity at 120° C. of 0.5 Pa's to 40.0 Pa·s.

8. The epoxy resin composition according to claim 1, wherein the curing accelerator is a heterocyclic compound containing a nitrogen atom.

9. The epoxy resin composition according to claim 1, comprising at least one curing agent selected from a phenolic curing agent, an amine-based curing agent, and an acid anhydride-based curing agent.

10. The epoxy resin composition according to claim 1, wherein the epoxy resin is at least one selected from an aliphatic epoxy resin and an aromatic epoxy resin.

11. The epoxy resin composition according to claim 1, which is used as a liquid compression molding material.

12. An electronic component comprising a support and the cured product of the epoxy resin composition according to claim 1.

13. A semiconductor device comprising the electronic component according to claim 12.

14. A method for manufacturing a semiconductor device, comprising: a step of filling a void between a support and a semiconductor element disposed on the support with the epoxy resin composition according to claim 1; a step of curing the epoxy resin composition; and a step of polishing a cured product of the epoxy resin composition.

15. The epoxy resin composition according to claim 2, wherein a content of the elastomer is 5.0 mass % or more with respect to components of the epoxy resin composition excluding the filler.

16. The epoxy resin composition according to claim 2, wherein the solid elastomer is a core-shell type.

17. The epoxy resin composition according to claim 3, wherein the solid elastomer is a core-shell type.

18. The epoxy resin composition according to claim 2, wherein a content of the elastomer is 5.0 mass % to 20.0 mass % with respect to components of the epoxy resin composition excluding the filler.

19. The epoxy resin composition according to claim 3, wherein a content of the elastomer is 5.0 mass % to 20.0 mass % with respect to components of the epoxy resin composition excluding the filler.

20. The epoxy resin composition according to claim 4, wherein a content of the elastomer is 5.0 mass % to 20.0 mass % with respect to components of the epoxy resin composition excluding the filler.
